(19) United States
(12) Patent Application Publication
(10) Pub. No.: US 2002/0055215 A1
(43) Pub. Date: May 9, 2002

(54) Semiconductor device and electronic equipment using same

(75) Inventors: Tsuyoshi Tamura, Hara-mura (JP); Norio Koizumi, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 09/981,734

(22) Filed: Oct. 19, 2001

(30) Foreign Application Priority Data
Oct. 26, 2000 (JP) 2000-326872

(51) Int. Cl. H01L 21/8238

(52) U.S. Cl. 438/200

(57) ABSTRACT

A semiconductor device is provided for various types of interfaces for performing various types of data processing operations based on input or output compressed data, and electronic equipment. A multiplexing/demultiplexing section demultiplexes compressed data compressed according to the MPEG-4 standard, for example, from multiplexed data which is multiplexed compressed data corresponding to various types of media, and supplies the demultiplexed and compressed data to output interface ICs corresponding to each output device including a display section. The output interface ICs decompress the demultiplexed and compressed data according to the MPEG-4 standard, for example. An input interface IC compresses data input from an input device according to the MPEG-4 standard, for example. The compressed data is supplied to the multiplexing/demultiplexing section and multiplexed therein.

Japanese Patent Application No. 2000-326872 filed Oct. 26, 2000 is hereby incorporated in its entirety.

### TECHNICAL FIELD

The present invention relates to a semiconductor device and electronic equipment using the same.

### BACKGROUND

Recent development of communications technology, mount technology, and the like has enabled the display of, not only numbers and characters, but also various types of data valuable for users as information such as still images and video, to be displayed in a display section of portable electronic equipment.

Various data formats have been proposed for data displayed in the electronic equipment. Taking a portable telephone as an example, technology of receiving or transmitting image data compressed and encoded according to the Moving Picture Experts Group (MPEG) standard has been proposed.

For example, the MPEG-4 standard takes into consideration various types of applications such as streaming distribution through the Internet, portable multimedia information terminals, and multimedia broadcasting. The MPEG-4 standard is standardized as a multimedia coding method capable of increasing efficiency of the conventional MPEG-1 and MPEG-2 coding standards. Moreover, the MPEG-4 standard enables object operations which realize synthesis of computer graphics (CG) images and music, and the like.

### SUMMARY

One aspect of the present invention provides a semiconductor device for output interface having an interface function with an output device, the semiconductor device comprising:

an input terminal to which compressed data is input;

a decompression section which decompresses the compressed data; and

an output terminal for outputting data decompressed by the decompression section to the output device.

Another aspect of the present invention provides a semiconductor device for input interface having an interface function with an input device, the semiconductor device comprising:

an input terminal to which uncompressed data is input from the input device;

a compression section which compresses the uncompressed data; and

an output terminal for outputting data compressed by the compression section.

A still another aspect of the present invention provides a semiconductor device for driving a display section, the semiconductor device comprising:

an input terminal to which compressed data is input;

a decompression section which decompresses the compressed data; and

an output terminal for outputting data decompressed by the decompression section to the display section.

### BRIEF DESCRIPTION OF THE DRAWINGS

FIGS. 1A and 1B are conceptual views showing the principle of multiplexing/demultiplexing of multiplexed data in an embodiment of the present invention and a conventional example;

FIG. 2 is a configuration diagram showing an outline of the principle of electronic equipment of this embodiment;

FIG. 3 is a block diagram showing an outline of the configuration of the electronic equipment of this embodiment;

FIG. 4 is a block diagram showing an example of the configuration of a display driver IC with a built-in MPEG-4 decoder of this embodiment;

FIG. 5 is a timing chart showing an example of operation timing of the display driver IC with a built-in MPEG-4 decoder of this embodiment;

FIG. 6 is a block diagram showing an outline of the configuration of electronic equipment of a first modification example;

FIG. 7 is a block diagram showing an outline of the configuration of electronic equipment of a second modification example; and

FIG. 8 is a block diagram showing an outline of the configuration of electronic equipment of a third modification example.

### DETAILED DESCRIPTION

An embodiment of the present invention is described below.

The embodiment described below should not be construed as limiting the scope of the present invention. The entire configuration described in this embodiment is not necessarily indispensable conditions for the present invention.

The MPEG-4 standard deals with wide variety of image formats ranging from a Quarter Common Intermediate Format (QCIF) to a High Definition Television (HDTV) with flexibility and covers from a low bit rate of less than 64 kbps (bit per second) to a high bit rate of 1.5 Mbps or more, and strengthens error robustness taking into consideration a wireless environment including mobile applications.

In the MPEG-4 standard, the most suitable profiles for various types of applications are standardized as an integrated standard. The simple profile is standardized for mobile applications as the most compact standard, in which only video coding and error robustness common to all the profiles are specified.

The MPEG-4 video coding standard enables video to be efficiently encoded using the Huffman coding by combining the Motion Compensated Interframe Prediction Coding (MC) and the Discrete Cosine Transform (DCT) in the same manner as in the MPEG-1 and MPEG-2 standards.

In the MPEG-4 error robustness standard, data recovery functions are secured by packetizing encoded data and inserting a resynchronization signal into every packet, or enabling decoding in the reverse direction for encoded data rows (bitstreams), for which lack of data is expected due to a wireless environment, by employing a Reversible Variable Length Code (RVLC).

Video and audio signals encoded according to the MPEG-4 standard are generally transmitted in amultiplexed state. The multiplexing is performed between video signals and audio signals which must be synchronized, or between these signals and other CG data, text data, and the like.

Therefore, various signals (video signal, audio signal, and the like) are demultiplexed by a decoder from a multiplexed bitstream. These signals are supplied to corresponding reproducing devices (display device and audio output device), whereby various types of multimedia information are output.

Conventionally, the decoder demultiplexes encoded video data and encoded audio data from the multiplexed bitstream, for example. Each piece of demultiplexed encoded data is supplied to a decoder circuit for MPEG-4 encoded video data and a decoder circuit for MPEG-4 encoded audio data. The decoder circuit for MPEG-4 encoded video data outputs a decoded video signal to a display section. The decoder circuit for MPEG-4 encoded audio data outputs a decoded audio signal to a speaker.

A decoder IC provided with decoder circuits for various types of MPEG-4 encoded data is integrated on a single chip. Data decoded by each decoder circuit is supplied to corresponding reproducing devices, thereby enabling output of multimedia information and the like.

However, in the case of applying such a single chip IC to portable telephones as mobile applications, for example, decoded information containing a large amount of data is transmitted through a bus provided inside the equipment. Therefore, current is consumed in driving a large amount of decoded data transmitted through a bus outside the IC, thereby increasing power consumption.

In the mobile applications, in the case of applying a general-purpose single chip IC as the MPEG-4 decoder circuits, such a single chip IC is generally over specification, thereby increasing the size, costs, and power consumption of the equipment. This makes it difficult to provide electronic equipment with optimum configuration meeting user needs. Therefore, it is preferable to provide only the most suitable decoder circuits for each piece of media information which makes up multimedia information.

An embodiment of the present invention has been achieved in view of the above technical problems. According to the embodiment is to provide a semiconductor device for various types of interfaces for performing various types of data processing operations based on the MPEG-4 standard compressed data as input-output data, for example, while consuming only a small amount of electric power, and electronic equipment using the semiconductor device.

The embodiment of the present invention provides a semiconductor device for output interface having an interface function with an output device, the semiconductor device comprising:

an input terminal to which compressed data is input;

a decompression section which decompresses the compressed data; and

an output terminal for outputting data decompressed by the decompression section to the output device.

In this embodiment, the decompression method is not limited. Various types of decompression methods can be applied.

The output device may have the same functions as those of an input device.

According to this embodiment, compressed data for which only a small amount of data transmission is needed is input to the input terminal of the semiconductor device for output interface having interface functions with the output device. The compressed data is decompressed and output to the output device from the output terminal. Therefore, current consumption accompanying data transmission can be decreased. Moreover, since only decompression operations corresponding to the output device connected to the output terminal are needed, costs for the semiconductor device can be decreased.

The embodiment of the present invention further provides a semiconductor device for input interface having an interface function with an input device, the semiconductor device comprising:

an input terminal to which uncompressed data is input from the input device;

a compression section which compresses the uncompressed data; and

an output terminal for outputting data compressed by the compression section.

In this embodiment, the compression method is not limited. Various types of compression methods can be applied.

The input device may have the same functions as those of an output device.

According to this embodiment, uncompressed data is input to the input terminal of the semiconductor device for input interface having interface functions with the input device from the input device. The uncompressed data is compressed and output from the output terminal. Therefore, current consumption accompanying data transmission to a bus connected to the output terminal can be decreased.

Moreover, since only compression operations corresponding to the input device connected to the input terminal are needed, costs for the semiconductor device can be decreased.

The embodiment of the present invention still further provides a semiconductor device for driving a display section, the semiconductor device comprising:

an input terminal to which compressed data is input;

a decompression section which decompresses the compressed data; and

an output terminal for outputting data decompressed by the decompression section to the display section.

In this embodiment, the decompression method is not limited. Various types of decompression methods can be applied.

According to this embodiment, compressed data for which only a small amount of data transmission is needed is input to the input terminal of the semiconductor device having interface functions with the display section. The compressed data is decompressed and output to the display section from the output terminal. Therefore, current consumption accompanying data transmission can be decreased. Moreover, since only decompression operations corresponding to display data displayed in the display section connected to the output terminal are needed, costs for the semiconductor device can be decreased.

In this embodiment, the compressed data input to the input terminal may be compressed data demultiplexed from multiplexed data which is multiplexed one or more types of compressed data, and the decompression section may decompress the demultiplexed and compressed data.

In this embodiment, the multiplexing method is not limited. Various types of multiplexing methods can be applied.

According to this embodiment, compressed data demultiplexed from the multiplexed data, which is multiplexed one or more types of compressed data, is input. The demultiplexed compressed data is decompressed. Therefore, the semiconductor device can be easily applied to devices capable of processing multimedia information multiplexed corresponding to various types of media.

In particular, since the semiconductor device has the most suitable configuration for the output device to be connected or display data displayed in the display section, costs and power consumption of the device to which the semiconductor device is applied can be decreased.

In this embodiment, the compressed data output from the output terminal may be multiplexed together with one or more types of compressed data.

In this embodiment, the multiplexing method is not limited. Various types of multiplexing methods can be applied.

According to this embodiment, the data compressed by the compression section is output from the output terminal. The output compressed data is multiplexed together with one or more types of compressed data. Therefore, the semiconductor device can be easily applied to devices capable of processing multimedia information multiplexed corresponding to various types of media.

In particular, since the semiconductor device has the most suitable configuration for the input device to be connected, costs and power consumption of the device to which the semiconductor device is applied can be decreased.

In this embodiment, the compressed data may be compressed according to a given compression standard.

According to this embodiment, the data is compressed or decompressed by performing general-purpose compression or decompression operations according to the standard, whereby the semiconductor device according to the present invention can be provided at low cost.

In this embodiment, the given compression standard may be an MPEG standard.

The embodiment of the present invention yet further provides electronic equipment comprising:

the above semiconductor device; and

a demultiplexing section which demultiplexes compressed data corresponding to the semiconductor device from multiplexed data which is multiplexed one or more types of compressed data, and supplies the demultiplexed and compressed data to the semiconductor device.

According to this embodiment, the compressed data demultiplexed from the multiplexed data which is multiplexed one or more types of compressed data is decompressed by the semiconductor device for output interface. Therefore, the electronic equipment can be easily applied to devices capable of processing multimedia information multiplexed corresponding to various types of media.

Moreover, since the compressed data is transmitted, power consumption and costs can be decreased, whereby electronic equipment with the most suitable configuration for the output device can be provided.

The embodiment of the present invention even further provides electronic equipment comprising:

the above semiconductor device; and

a multiplexing section which generates multiplexed data by multiplexing one or more types of compressed data including compressed data supplied from the semiconductor device.

According to this embodiment, the multiplexing section generates the multiplexed data in which the compressed data obtained by compressing the uncompressed data input from the input device by the semiconductor device for input interface is multiplexed together with one or more types of compressed data. Therefore, the electronic equipment can be easily applied to devices capable of processing multimedia information multiplexed corresponding to various types of media.

Moreover, since the compressed data is transmitted, power consumption and costs can be decreased, whereby electronic equipment with the most suitable configuration for the input device can be provided.

The embodiment of the present invention yet still further provides electronic equipment comprising:

the above semiconductor device;

a demultiplexing section which demultiplexes compressed data corresponding to the semiconductor device from multiplexed data which is multiplexed one or more types of compressed data, and supplies the demultiplexed and compressed data to the semiconductor device; and

a display section which is driven by the semiconductor device.

According to this embodiment, the compressed data demultiplexed from the multiplexed data which is multiplexed one or more types of compressed data is decompressed by the semiconductor device for driving a display. Therefore, the electronic equipment can be easily applied to devices capable of processing multimedia information multiplexed corresponding to various types of media.

Moreover, since the compressed data is transmitted, power consumption and costs can be decreased, whereby electronic equipment with the most suitable configuration for display data displayed in the display section can be provided.

The electronic equipment according to this embodiment may comprise a circuit which transmits and receives the multiplexed data through a given communication network.

This enables the provision of portable telephones and portable information terminals capable of decreasing costs and power consumption.

In this embodiment, the compressed data may be compressed according to a given compression standard.

According to this embodiment, since the data is compressed or decompressed by performing general-purpose compression or decompression operations according to the standard, the electronic equipment according to the present invention can be provided at low cost.

In this embodiment, the given compression standard may be the MPEG standard.

An embodiment of the present invention is described below in detail with reference to the drawings.

1. Feature of the Present Embodiment

The features of this embodiment are described below while comparing this embodiment with a conventional example.

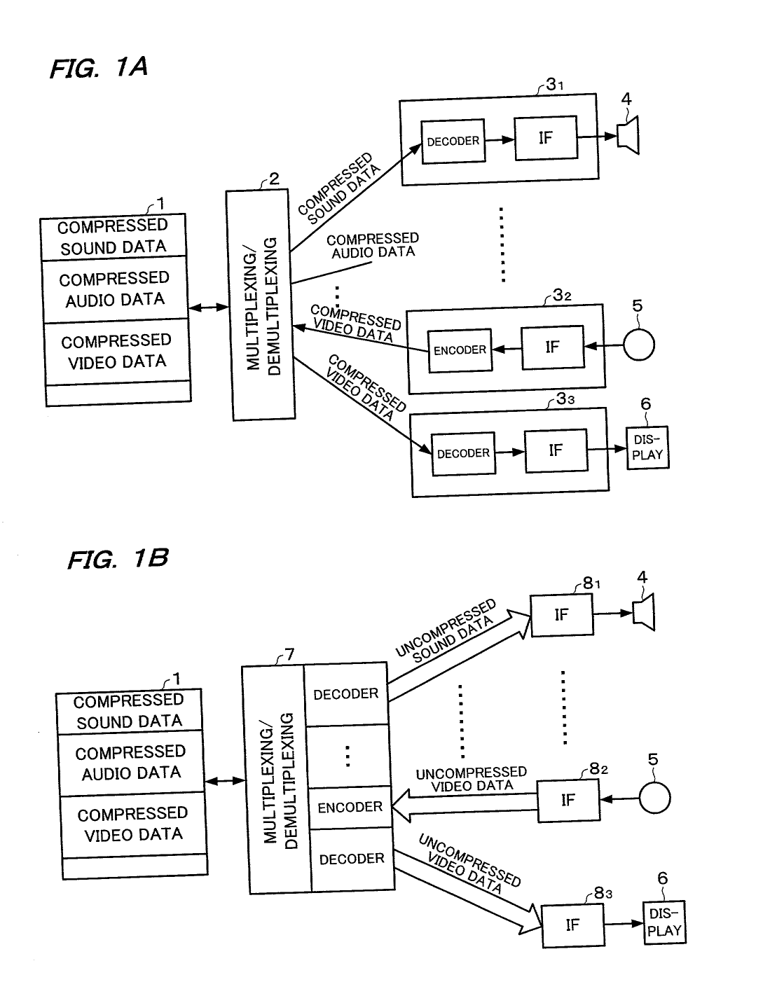

FIG. 1A is a conceptual view showing the principle of multiplexing/demultiplexing of multiplexed data in this embodiment. FIG. 1B is a conceptual view showing the principle of multiplexing/demultiplexing of multiplexed data in a conventional example.

In this embodiment, multiplexed data 1 in which sound data, audio data, and video data compressed by a given compression standard are multiplexed is demultiplexed into compressed sound data, compressed audio data, and compressed video data by a multiplexing/demultiplexing circuit 2, as shown in FIG. 1A.

The demultiplexed compressed sound data is decoded in a sound output interface section 3₁ according to the given compression standard, and output to a speaker 4 through an IF circuit, for example. The demultiplexed compressed video data is decoded in an image output interface section 3₃ according to the MPEG-4 standard, for example, and output to a display section 6 through an IF circuit.

A video signal input from a camera 5 is encoded in an image input interface section 32 by an encoder through an IF circuit according to the MPEG-4 standard, for example, and supplied to the multiplexing/demultiplexing circuit 2.

The multiplexing/demultiplexing circuit 2 multiplexes the compressed video data input from the image input interface section 3₂ to generate the multiplexed data 1.

In a conventional example, the multiplexed data 1 in which sound data, audio data, and video data compressed by a given compression standard are multiplexed is input to a compression/decompression circuit 7 including a multiplexing/demultiplexing circuit and decoders and encoders for each piece of compressed data, as shown in FIG. 1B.

The multiplexing/demultiplexing circuit of the compression/decompression circuit 7 demultiplexes compressed sound data, compressed audio data, and compressed video data from the multiplexed data 1.

The demultiplexed compressed sound data is decoded by the decoder of the compression/decompression circuit 7 according to a given compression standard, transmitted to an IF circuit 81, and output to the speaker 4, for example. The demultiplexed compressed video data is decoded by the decoder of the compression/decompression circuit 7 according to the MPEG-4 standard, for example, transmitted to an IF circuit 8₃, and output to the display section 6.

A video signal input from the camera 5 is transmitted to the compression/decompression circuit 7 through an IF circuit 82, and encoded by the encoder of the compression/decompression circuit 7 according to the MPEG-4 standard, for example.

The encoded compressed video data is multiplexed by the multiplexing/demultiplexing circuit of the compression/decompression circuit 7, whereby the multiplexed data 1 is generated.

In a conventional example, a compression/decompression circuit including general-purpose or over specification decoders or encoders is provided, as shown in FIG. 1B. Moreover, uncompressed data is transmitted to each IF circuit. On the contrary, in this embodiment, since the compressed data for which only a small amount of data transmission is needed is transmitted to each interface section as shown in FIG. 1A, current consumption for driving a bus can be decreased.

Moreover, since a decoder or an encoder according to the standard corresponding to the input-output devices such as the speaker 4, the camera 5, and the display section 6 can be provided in each interface section, the device configuration can be optimized.

Electronic equipment of this embodiment having the above features is described below.

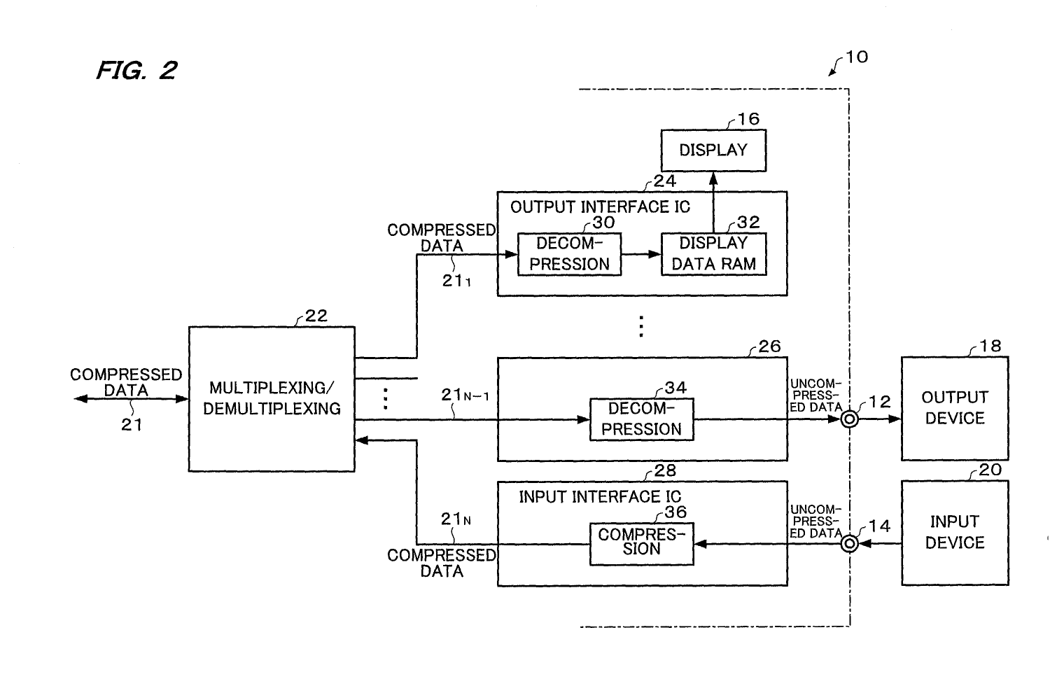

FIG. 2 shows an outline of the configuration of the electronic equipment of this embodiment.

Electronic equipment 10 of this embodiment includes an output terminal 12 and an input terminal 14 as external terminals connected to various types of external input-output devices. The electronic equipment 10 further includes a display section 16 capable of displaying various types of information as a portable terminal.

The electronic equipment 10 is connected to an output device 18 through the output terminal 12, and connected to an input device 20 through the input terminal 14. Various types of media information is output to or input from each device.

The display section 16 displays various types of information as a portable terminal based on display data including moving image data or still image data. The display section 16 can be a display unit including a color liquid crystal panel which is an example of a matrix panel including an electro-optic device, for example.

The output device 18 can be hardware such as a speaker which outputs sound (voice) data or a headphone which outputs audio data, for example.

The input device 20 can be hardware such as a camera which generates moving image data or still image data or a microphone which generates sound data, for example.

In the electronic equipment 10 of this embodiment, each IC which makes up the equipment is connected through a compressed data bus 21. Data compressed by the MPEG-4 standard, for example, corresponding to each medium (display section 16, output device 18, and input device 20 in a broad sense) is transmitted through the compressed data bus 21 in a multiplexed state. Compressed data corresponding to each medium is demultiplexed from the multiplexed data by a multiplexing/demultiplexing section 22, and supplied to each device through compressed data buses 21₁ to 21_{N}, respectively.

Therefore, the electronic equipment 10 includes interface ICs (semiconductor devices in a broad sense) 24, 26, and 28 corresponding to each input-output (I/O) device such as the output terminal 12, the input terminal 14, and the display section 16, and has interface functions between the circuits inside the electronic equipment 10 and the input-output devices outside the electronic equipment 10.

More specifically, the output interface IC 24 corresponding to the display section 16 is provided with a built-in display driver (not shown), and includes a decompression section 30 which decodes the compressed data demultiplexed from the multiplexed data by a multiplexing/demultiplexing section 22 according to the MPEG-4 video standard, for example, and a display data RAM 32 which stores display data as uncompressed data decompressed by the decompression section 30. Display data for one frame is read from the display data RAM 32 every 1/60th of a second, for example. The display section 16 is driven by the display driver (not shown) of the output interface IC 24.

The output interface IC 26 corresponding to the output terminal 12 connected to the output device 18 includes a decompression section 34 which decodes the compressed data demultiplexed from the multiplexed data by the multiplexing/demultiplexing section 22 according to the MPEG-4 audio standard, for example. The output interface IC 26 outputs an audio signal and the like to the output device 18 as data decompressed by the decompression section 34.

The input interface IC 28 corresponding to the input terminal 14 connected to the input device 20 includes a compression section 36 which encodes uncompressed data such as a sound (voice) signal or a video signal input from the input device 20 through the input terminal 14 according to the MPEG-4 video standard, for example. The input interface IC 28 outputs data compressed by the decompression section 36 to the multiplexing/demultiplexing section 22.

The multiplexing/demultiplexing section 22 demultiplexes the multiplexed data input through the compressed data bus 21 into compressed data corresponding to each medium, and supplies the compressed data to the output interface ICs 24 and 26. The multiplexing/demultiplexing section 22 multiplexes the compressed data input from the input interface IC 28 and the like, and outputs the multiplexed data to the compressed data bus 21.

In this embodiment, the multiplexing/demultiplexing section 22 demultiplexes the data compressed according to the MPEG-4 standard, for example, from the multiplexed data, and supplies the compressed data to the output interface ICs corresponding to each output device including the display section 16. The output interface ICs decompress (decode) the compressed data according to the MPEG-4 standard, for example.

The input interface IC compresses data input from the input device according to the MPEG-4 standard, for example. The compressed data is supplied to the multiplexing/demultiplexing section 22 and multiplexed therein.

This significantly decreases the current consumption for driving a signal to the uncompressed data bus through which the uncompressed data containing a smaller amount of data is transmitted.

Moreover, each interface IC can be provided with a decoder circuit or an encoder circuit which utilizes only a coding or decoding method suitable for the display section 16 or the input-output devices. As a result, power consumption and costs can be decreased.

The electronic equipment in this embodiment is described below in more detail.

2. Electronic Equipment of Present Embodiment

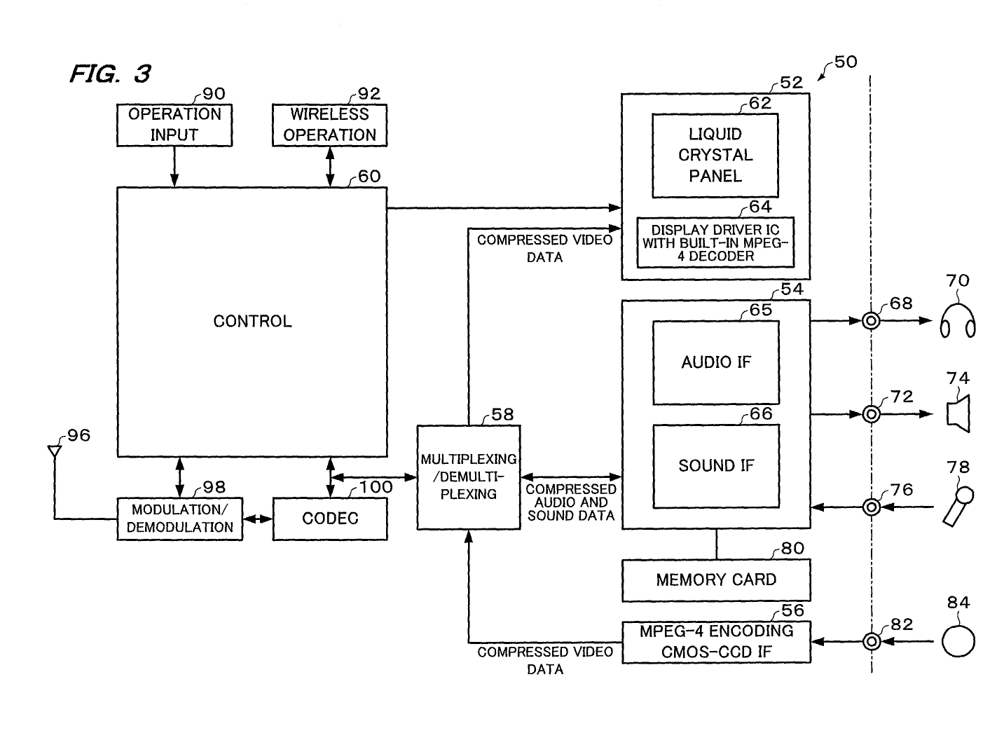

FIG. 3 shows an outline of the configuration of the electronic equipment in this embodiment.

Electronic equipment 50 includes a display unit 52, a sound processing IC 54, a CMOS-CCD (Charge Coupled Device) interface circuit 56, a multiplexing/demultiplexing circuit 58, and a control circuit 60.

The display unit 52 includes a matrix panel having an electro-optic device such as a color liquid crystal panel (display section in a broad sense) 62, and a display driver IC (output interface IC in abroad sense) 64 with a built-in MPEG-4 decoder which includes a built-in display data RAM for storing moving image data or still image data for at least one frame, and drives the liquid crystal panel 62.

The liquid crystal panel 62 includes an electro-optic device such as a liquid crystal of which the optical characteristics are changed by applying a voltage. A simple matrix panel may makeup the liquid crystal panel 62, for example. In this case, a liquid crystal is sealed between a first substrate on which a plurality of segment electrodes (first electrodes) is formed, and a second substrate on which a plurality of common electrodes (second electrodes) is formed. The liquid crystal panel 62 may be an active matrix panel using a three terminal device such as a thin film transistor (TFT) or a thin film diode (TFD) or a two terminal device. The active matrix panel includes a plurality of signal electrodes (first electrodes) driven by the display driver IC 64 with a built-in MPEG-4 decoder, and a plurality of scanning electrodes (second electrodes) driven by scanning.

The liquid crystal panel 62 is capable of displaying a still image and moving image at the same time. In this case, a moving image display region specified by the image size of moving image data and a still image display region (text data display region) are set in the display region of the liquid crystal panel 62. Display data for one frame is read from the display data RAM included in the display driver IC 64 with a built-in MPEG-4 decoder every 1/60th of a second, for example, whereby moving image and a still image are displayed.

The display driver IC 64 with a built-in MPEG-4 decoder includes the display data RAM which stores display data for at least one frame. The display driver IC 64 decompresses the compressed moving image data supplied from the multiplexing/demultiplexing circuit 58 according to the MPEG-4 standard, and stores the decompressed data in the display data RAM as moving image data or still image data. The control circuit 60 allows the display driver IC 64 with a built-in MPEG-4 decoder to supply text data as the display data, or to set the moving image display region and the still image display region.

The sound processing IC 54 includes an audio interface circuit 65 and a sound interface circuit 66.

More specifically, the audio interface circuit 65 generates uncompressed data by decoding MPEG-4 compressed audio data or MPeg audio layer 3 (MP3) compressed audio data supplied from the multiplexing/demultiplexing circuit 58. The audio interface circuit 65 converts the uncompressed data into an analog signal by D/A conversion, and outputs an audio signal to a headphone 70 or a speaker 74 connected through an output terminal 68, for example.

The sound interface circuit 66 generates uncompressed data by decoding compressed sound data using the Global System for Mobile Communication-Adaptive Multi-Rate Coding (GSM-AMR) or the Transform Domain Weighted INterleave Vector Quantization (TwinVQ). The sound interface circuit 66 converts the uncompressed data into an analog signal by D/A conversion, and outputs a sound signal to the speaker 74 through an output terminal 72, for example. The sound interface circuit 66 converts a sound signal input from a microphone 78 through an input terminal 76 into a digital signal by A/D conversion. The sound interface circuit 66 generates compressed data by encoding the digital signal into compressed sound data using GSM-ARM or TwinVQ, and outputs the compressed data to the multiplexing/demultiplexing circuit 58.

The sound processing IC 54 may be designed so that a removable memory card 80 is connected to the electronic equipment 50 of this embodiment, and the compressed sound data using GSM-ARM or TwinVQ is stored in the memory card 80. As the memory card 80, memory cards according to various standards can be applied.

The MPEG-4 encoder CMOS-CCD camera interface circuit 56 generates compressed video data by encoding a video signal input from a CMOS-CCD camera 84 through an input terminal 82 according to the MPEG-4 video standard, and outputs the compressed video data to the multiplexing/demultiplexing circuit 58.

The multiplexing/demultiplexing circuit 58 demultiplexes compressed video data in which display data for the display unit 52 is compressed and compressed audio data or compressed sound data supplied to the sound processing IC 54 from the multiplexed compressed data in which compressed data corresponding to each medium is multiplexed. The multiplexing/demultiplexing circuit 58 generates multiplexed compressed data by multiplexing the compressed video data compressed by the MPEG-4 encoder CMOS-CCD camera interface circuit 56 and the compressed audio data or compressed sound data compressed by the sound processing IC 54.

The electronic equipment 50 of this embodiment is capable of transmitting or receiving the multiplexed compressed data input to or output from the multiplexing/demultiplexing circuit 58 through a wireless communications network such as a mobile communications network, as the same functions as the communication functions of portable telephones.

Therefore, the electronic equipment 50 includes an operation input section 90 to which operation information is input by operating keys, and a wireless operation section 92 for performing wireless operations by Bluetooth which is short distance wireless communications technology, and the like. These sections are controlled by the control circuit 60.

The control circuit 60 includes a CPU and a memory (not shown) so that a series of transmission and reception processing can be performed through a wireless communications network according to a control program stored in the memory. Operation information necessary for data transmission and reception of the electronic equipment 50 is input through the operation input section 90.

The electronic equipment 50 includes a modulator/demodulator circuit 98 which demodulates a signal received through an antenna 96, or modulates a signal to be transmitted through the antenna 96. Moving image data encoded according to the MPEG-4 standard, for example, can be transmitted or received through the antenna 96.

A signal input through the antenna 96 is demodulated through the modulator/demodulator circuit 98 and decoded by a CODEC circuit 100. As a result, multiplexed compressed data supplied to the demultiplexing circuit 58 or received data to be processed by the control circuit 60 is generated, for example.

Data transmitted through the modulator/demodulator circuit 98 and the antenna 96 is transmission data from the control circuit 60 or multiplexed compressed data from the multiplexing/demultiplexing circuit 58 encoded by the CODEC circuit 100.

As described above, the control circuit 60 allows data to be transmitted or received according to instructions input through the operation input section 90 or the wireless operation section 92 by controlling the modulator/demodulator circuit 98 and the CODEC circuit 100 based on the control program. For example, the control circuit 60 outputs text data to the display unit 52 or sets the display region of the display unit 52 based on the data received from the CODEC circuit 100. The control circuit 60 outputs transmission data generated according to instructions from the operation input section 90 or the like to the CODEC circuit 100, and allows the data to be transmitted through the antenna 96.

In the electronic equipment 50 having the above configuration, in the case where the data received by the antenna 96 through a wireless communications network and decoded by the CODEC circuit 100 is the multiplexed compressed data, the multiplexing/demultiplexing circuit 58 demultiplexes the received data into compressed data as bitstream data corresponding to each medium, and supplies the data to the corresponding output interface ICs. Compressed data encoded by the input interface IC is multiplexed by the multiplexing/demultiplexing circuit 58. The multiplexed compressed data is encoded by the CODEC circuit 100 and transmitted to the wireless communications network through the antenna 96 according to instructions from the operation input section 90, for example.

Therefore, in the case where the signal received through the wireless communications network is the multiplexed compressed data, the signal is demultiplexed in a compressed state according to the MPEG-4 standard, for example, and transmitted to the interface ICs for the display section or each input-output device. Specifically, since the ICs inside the electronic equipment can be connected in a state in which the amount of data to be transmitted is decreased, the amount of current consumed in driving the bus can be significantly decreased.

In particular, since each interface IC includes a decoder circuit or an encoder circuit according to the MPEG-4 standard, the number of busses through which uncompressed data is transmitted corresponding to each medium is decreased, whereby the power consumption can be decreased effectively.

Moreover, allowing each interface IC to include a decoder circuit or an encoder circuit enables applying a decoder circuit or an encoder circuit corresponding to the MPEG-4 profile for the input-output device to be connected, whereby miniaturization of the equipment and optimization of the configuration can be easily achieved.

3. Semiconductor Device of Present Embodiment

The interface ICs (semiconductor devices in a broad sense) used for the electronic equipment of this embodiment are described below taking the display driver IC 64 with a built-in MPEG-4 decoder as an example.

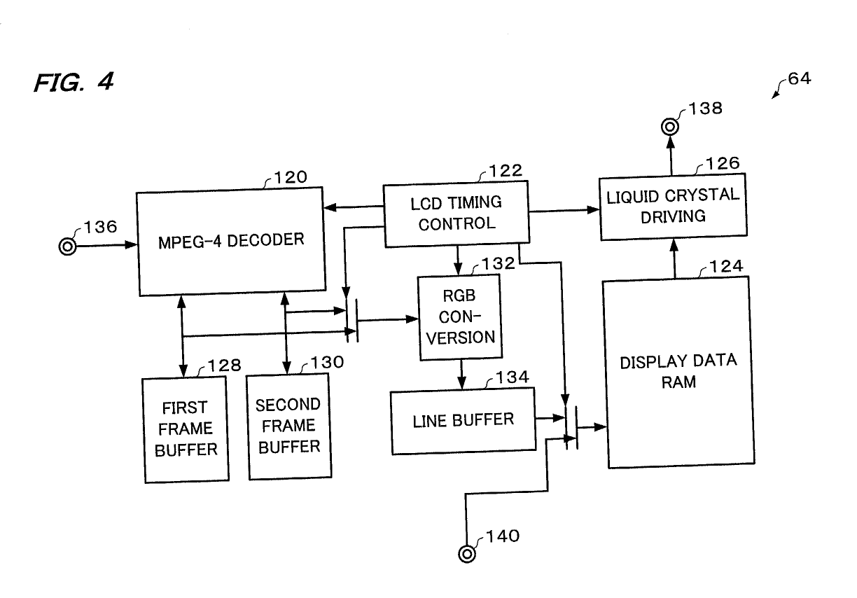

FIG. 4 shows an example of the constituent blocks for the display driver IC with a built-in MPEG-4 decoder of this embodiment.

The display driver IC 64 with a built-in MPEG-4 decoder includes an MPEG-4 decoder circuit 120, an LCD timing control circuit 122, a display data RAM 124, a liquid crystal driving circuit 126, first and second frame buffers 128 and 130, an RGB conversion circuit 132, and a line buffer 134.

The MPEG-4 decoder circuit 120 decodes a bitstream, which is compressed data input from an input terminal 136, according to the MPEG-4 standard, and stores the decoded data in one of the first and second frame buffers 128 and 130 as display data for one frame. At this time, the MPEG-4 decoder circuit 120 decodes the bitstream while referring to the display data in the previous frame buffered therein to generate the display data in the current frame, for example.

The LCD timing control circuit 122 reads the display data for one frame from the display data RAM 124 every 1/60th of a second, for example, thereby generating timing at which the liquid crystal panel is driven by the liquid crystal driving circuit 126 connected to a signal electrode 138 for driving each electrode of the liquid crystal panel. The LCD timing control circuit 122 controls the timing of the entire display driver IC 64 with a built-in MPEG-4 decoder.

Specifically, the LCD timing control circuit 122 instructs the MPEG-4 decoder circuit 120 on read timing for reading the display data for one frame from one of the first and second frame buffers 128 and 130. The LCD timing control circuit 122 outputs instructions relating to write timing for writing the display data for one frame read from one of the first and second frame buffers 128 and 130 to the display data RAM 124.

More specifically, the LCD timing control circuit 122 reads the display data for one frame from one of the first and second frame buffers 128 and 130, and supplies the display data to the RGB conversion circuit 132.

The LCD timing control circuit 122 causes the display data decoded by the MPEG-4 decoder circuit 120 to be written into the frame buffer from which the display data is not output to the RGB conversion circuit 132. This prevents read and write operations from being simultaneously performed for the same frame buffer.

The RGB conversion circuit 132 converts the display data in YUV format stored in the first and second frame buffers 128 and 130 into display data in RGB format. The display data for one frame in RGB format converted by the RGB conversion circuit 132 is buffered into the line buffer 134 in scanning line units.

The display data buffered into the line buffer 134 or text data input from the external control circuit 60 through an input terminal 140 is written into the display data RAM 124 according to instructions from the LCD timing control circuit 122. In the case where the moving image display region and the still image display region are set by the control circuit 60, for example, the buffered display data or text data is written into the storage region of the display data RAM 124 corresponding to the specified display region.

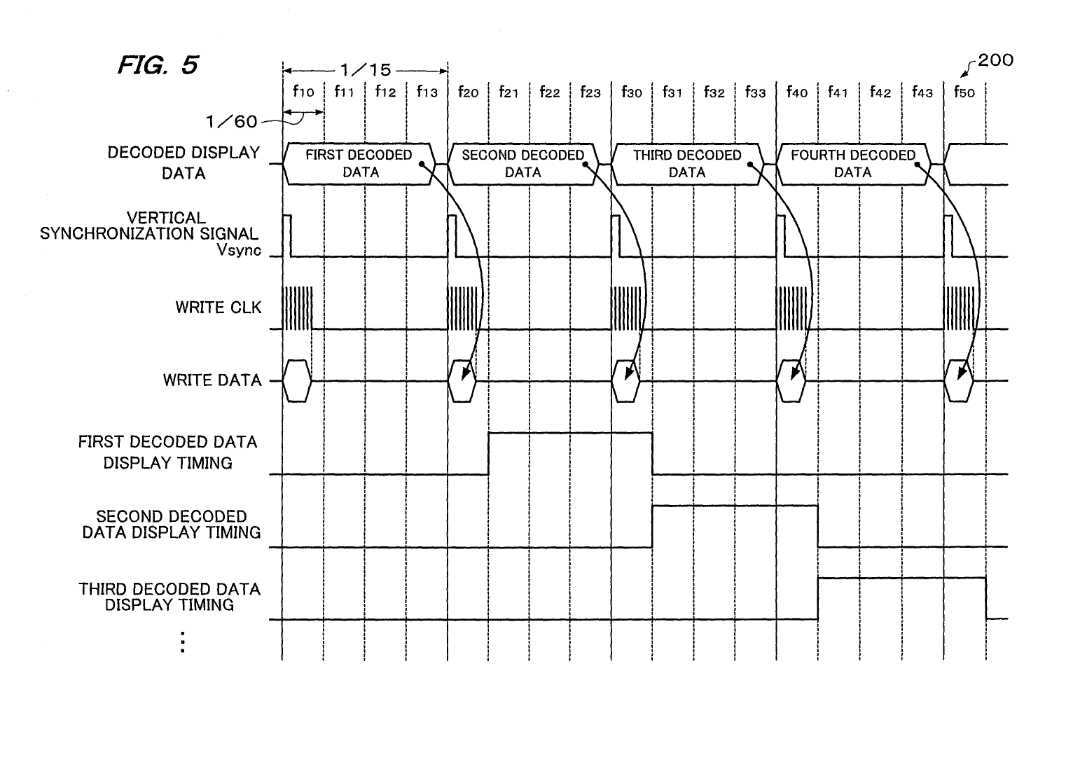

FIG. 5 shows an example of the operation timing for the display driver IC with a built-in MPEG-4 decoder of this embodiment.

In this example, the display data is decoded by the MPEG-4 decoder circuit 120 from the input bitstream at a rate of 15 frames per second or more, and the display data for one frame is stored in one of the first and second frame buffers 128 and 130.

The LCD timing control circuit 122 generates a write clock for writing the display data for scanning lines for a specific image size based on a vertical synchronization signal Vsync showing the head of the decoded display data for one frame.

The write speed of the decoded display data for one frame is either the same as or higher than the read speed of the display data for one frame. In the case where the liquid crystal panel is driven by allowing the display data to be read from the display data RAM 124 every 1/60th of a second, for example, the display data for one frame is written into the display data RAM 124 at a rate of 1/60th of a second or less.

Specifically, the display data for one frame decoded by the MPEG-4 decoder circuit 120 within 1/15th of a second (phases f₁₀ to f₁₃) is written at a phase f₂₀ as the display data for one frame in the previous frame according to the write clock signal generated based on the vertical synchronization signal Vsync showing the head of the display data in the next frame.

In this example, the display data in the previous frame is written based on the vertical synchronization signal Vsync in the next frame. However, the display data may be written after a given period of time has elapsed taking into consideration the intervals for reading the display data.

The LCD timing control circuit 122 generates the display timing for one frame decoded between phases f₁₀ to f₁₃ and written into the display data RAM 124 at the phase f₂₀ between phases f₂₁ to f₃₀. Since the LCD timing control circuit 122 reads the display data from the display data RAM 124 every 1/60th of a second, the LCD timing control circuit 122 reads the same display data during four continuous phases.

The display data for one frame decoded between the phases f₂₀ to f₂₃ and written into the display data RAM 124 at the phase f₃₀ is read between phases f₃₁ to f₄₀ and displayed.

4. Modification Example

The electronic equipment of this embodiment is not limited to the configuration shown in FIG. 3, for which various modification examples are possible.

4.1 First Modification Example

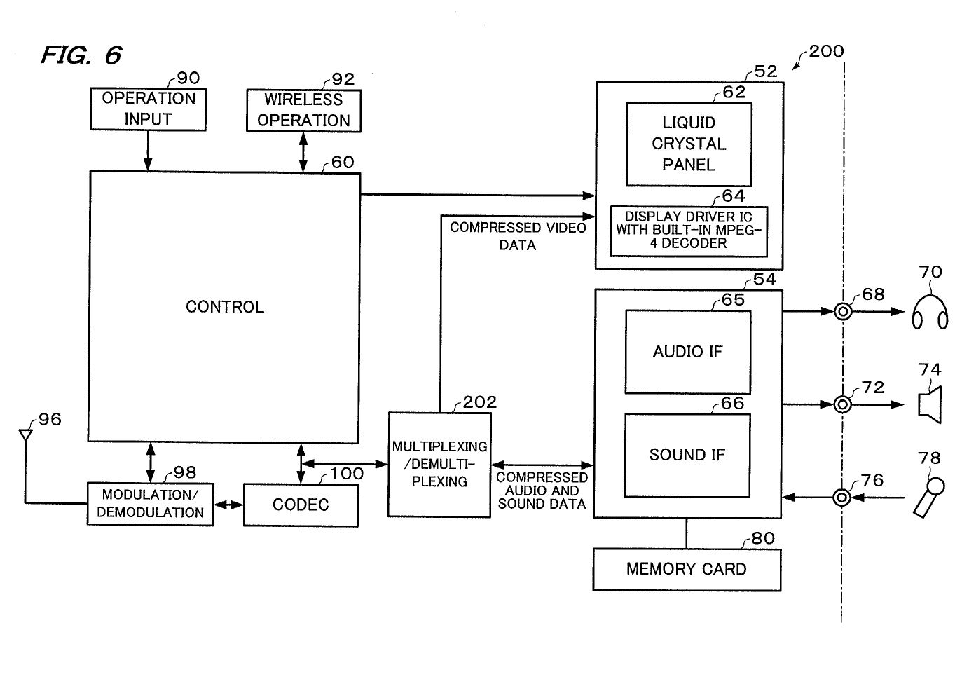

FIG. 6 shows an outline of the configuration of electronic equipment of a first modification example.

Sections the same as those of the electronic equipment of this embodiment shown in FIG. 3 are indicated by the same symbols. Description of these sections is appropriately omitted.

Electronic equipment 200 of the first modification example includes the display unit 52, the sound processing IC 54, a multiplexing/demultiplexing circuit 202, and the control circuit 60.

The difference between the electronic equipment 200 of the first modification example and the electronic equipment 50 of this embodiment is that the CMOS-CCD camera interface circuit 56 and the input terminal 82 corresponding thereto are not provided.

Therefore, the multiplexing/demultiplexing circuit 202 of the first modification example demultiplexes compressed video data in which display data for the display unit 52 is compressed and compressed audio data or compressed sound data output from the sound processing IC 54, from the compressed data in which compressed data corresponding to each medium is multiplexed. The multiplexing/demultiplexing circuit 202 generates multiplexed compressed data by multiplexing audio data or sound data compressed by the sound processing IC 54.

According to the electronic equipment 200 having the above configuration, in the case where the signal received through a wireless communications network is a bitstream which is the multiplexed compressed data, the signal is demultiplexed in a compressed state according to the MPEG-4 standard, for example, and transmitted to the interface ICs for the display section or each input-output device. This significantly decreases the amount of current consumed in driving the bus.

In particular, since each interface IC includes a decoder circuit or an encoder circuit according to the MPEG-4 standard, the number of busses through which the uncompressed data corresponding to each medium is transmitted is decreased, whereby the power consumption can be decreased effectively.

Moreover, allowing each interface IC to include a decoder circuit or an encoder circuit enables applying a decoder circuit or an encoder circuit corresponding to the MPEG-4 profile for the input-output devices to be connected, whereby miniaturization of the equipment and optimization of the configuration can be easily achieved.

4.2 Second Modification Example

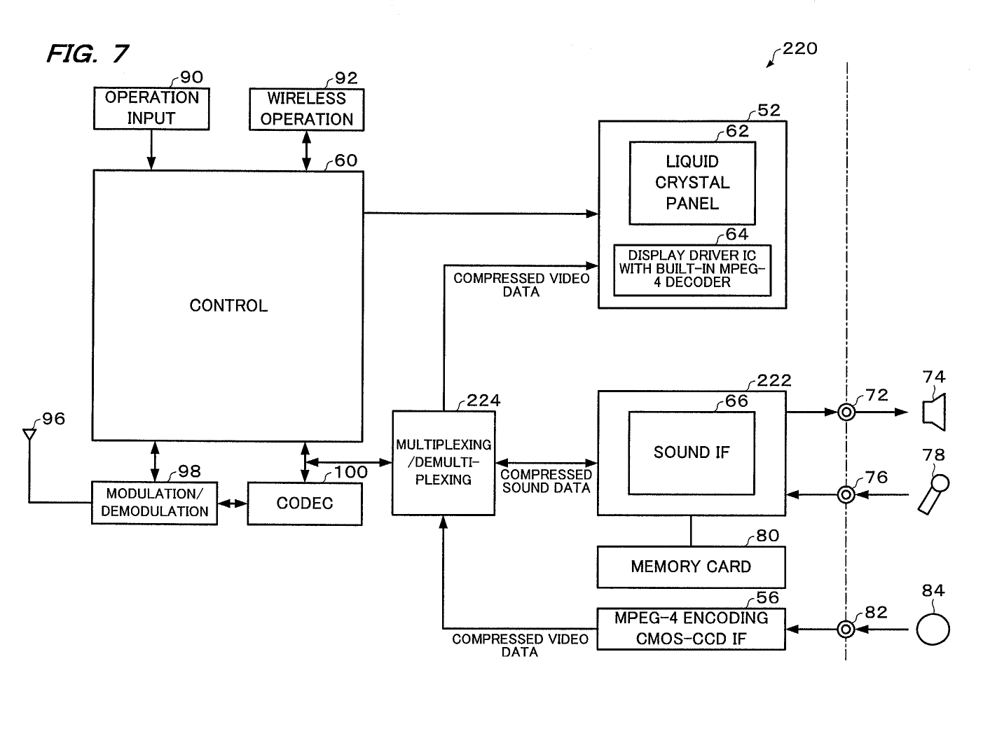

FIG. 7 shows an outline of the configuration of electronic equipment of a second modification example.

Sections the same as those of the electronic equipment of this embodiment shown in FIG. 3 are indicated by the same symbols. Description of these sections is appropriately omitted.

Electronic equipment 220 includes the display unit 52, a sound processing IC 222, the CMOS-CCD camera interface circuit 56, a multiplexing/demultiplexing circuit 224, and the control circuit 60.

The difference between the electronic equipment 220 of the second modification example and the electronic equipment 50 of this embodiment is that the sound processing IC 222 does not include the audio interface circuit 65 and the output terminal 68 corresponding thereto is not provided.

Therefore, the sound processing IC 222 generates uncompressed data by decoding compressed sound data encoded using GSM-AMR or TwinVQ by the sound interface circuit 66. The sound processing IC 222 converts the uncompressed data into an analog signal by D/A conversion, and outputs a sound signal to the speaker 74 through the output terminal 72, for example. The sound processing IC 222 converts a sound signal input from the microphone 78 through the input terminal 76 into a digital signal by A/D conversion. The sound processing IC 222 generates compressed data by encoding the digital signal into compressed sound data using GSM-AMR or TwinVQ, and outputs the compressed data to the multiplexing/demultiplexing circuit 224.

The sound processing IC 222 may be designed so that the removable memory card 80 is connected to the electronic equipment 220 of the second modification example, and the compressed sound data using GSM-ARM or TwinVQ is stored in the memory card 80.

The multiplexing/demultiplexing circuit 224 demultiplexes the compressed video data in which the display data for the display unit 52 is compressed and compressed audio data or compressed sound data to be decoded by the sound processing IC 222, from the multiplexed compressed data in which the compressed data corresponding to each medium is multiplexed. The multiplexing/demultiplexing circuit 224 generates multiplexed compressed data by multiplexing video data compressed by the MPEG-4 encoder CMOS-CCD camera interface circuit 56 and audio data or sound data compressed by the sound processing IC 222.

According to the electronic equipment 220 having the above configuration, in the case where the signal received through the wireless communications network is a bitstream which is the multiplexed compressed data, the signal is demultiplexed in a compressed state according to the MPEG-4 standard, for example, and transmitted to the interface ICs for the display section or each input-output device. This significantly decreases the amount of current consumed in driving the bus.

In particular, since each interface IC includes a decoder circuit and an encoder circuit according to the MPEG-4 standard, the number of busses through which the uncompressed data corresponding to each medium is transmitted can be decreased, whereby the power consumption can be decreased effectively.

Moreover, allowing each interface IC to include a decoder circuit or an encoder circuit enables applying a decoder circuit or an encoder circuit corresponding to the MPEG-4 profile for the input-output devices to be connected, whereby miniaturization of the equipment and optimization of the configuration can be easily achieved.

4.3 Third Modification Example

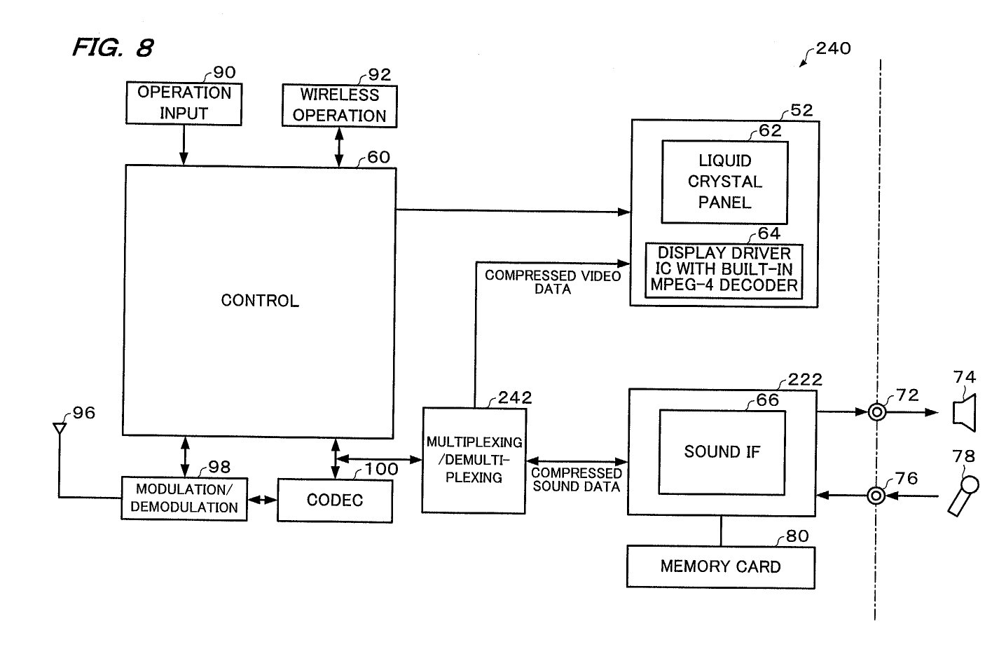

FIG. 8 shows an outline of the configuration of electronic equipment of a third modification example.

Sections the same as those of the electronic equipment of this embodiment shown in FIG. 3 and the electronic equipment of the second modification example shown in FIG. 7 are indicated by the same symbols. Description of these sections is appropriately omitted.

Electronic equipment 240 of the third modification example includes the display unit 52, the sound processing IC 222, a multiplexing/demultiplexing circuit 242, and the control circuit 60.

The difference between the electronic equipment 240 of the third modification example and the electronic equipment 50 of this embodiment is that the CMOS-CCD camera interface circuit 56 and the input terminal 82 corresponding thereto are not provided, the sound processing IC 222 does not include the audio interface circuit 65, and the output terminal 68 corresponding thereto is not provided.

Therefore, the multiplexing/demultiplexing circuit 224 demultiplexes compressed video data in which the display data for the display unit 52 is compressed and compressed audio data or compressed sound data to be decoded by the sound processing IC 222, from the multiplexed compressed data in which the compressed data corresponding to each medium is multiplexed. The multiplexing/demultiplexing circuit 224 generates multiplexed compressed data by multiplexing sound data compressed by the sound processing IC 222.

According to the electronic equipment 240 having the above configuration, in the case where the signal received through the wireless communications network is the multiplexed compressed data, the signal is demultiplexed in a compressed state according to the MPEG-4 standard, for example, and transmitted to the interface ICs for the display section or each input-output unit. Specifically, each IC contained in the equipment can be connected in a state in which the amount of data to be transmitted is decreased, whereby the amount of current consumed in driving the bus can be significantly decreased.

In particular, since each interface IC includes a decoder circuit and an encoder circuit according to the MPEG-4 standard, the number of busses through which uncompressed data corresponding to each medium is transmitted can be decreased, whereby the power consumption can be decreased effectively.

Moreover, allowing each interface IC to include a decoder circuit or an encoder circuit enables applying a decoder circuit or an encoder circuit corresponding to the MPEG-4 profile for the input-output devices to be connected, whereby miniaturization of the equipment and optimization of the configuration can be easily achieved.

The present invention is not limited to this embodiment and the first to third modification examples. Various modifications and variations are possible without departing from the scope of the present invention.

For example, in the present invention, the multiplexing method, the demultiplexing method, and the wireless communications network are not limited.

This embodiment and the first to third modification examples illustrate examples including a decoder circuit and an encoder circuit according to the MPEG-4 standard for performing compression and decompression operations. However, the present invention is not limited thereto. In the present invention, the compression method or decompression method for video data, sound data, or audio data are not limited. Various types of compression standards can be applied.

This embodiment and the first to third modification examples illustrate examples in which the interface ICs are connected to the input-output devices through the input terminal or the output terminal as an external terminal. However, the present invention can be applied to the case where input-output devices are provided in the electronic equipment.

What is claimed is:

1. A semiconductor device for output interface having an interface function with an output device, the semiconductor device comprising:
an input terminal to which compressed data is input;
a decompression section which decompresses the compressed data; and
an output terminal for outputting data decompressed by the decompression section to the output device.

2. A semiconductor device for input interface having an interface function with an input device, the semiconductor device comprising:
an input terminal to which uncompressed data is input from the input device;
a compression section which compresses the uncompressed data; and
an output terminal for outputting data compressed by the compression section.

3. A semiconductor device for driving a display section, the semiconductor device comprising:
an input terminal to which compressed data is input;
a decompression section which decompresses the compressed data; and
an output terminal for outputting data decompressed by the decompression section to the display section.

4. The semiconductor device according to claim 1,
wherein the compressed data input to the input terminal is compressed data demultiplexed from multiplexed data which is multiplexed one or more types of compressed data, and
wherein the decompression section decompresses the demultiplexed and compressed data.

5. The semiconductor device according to claim 2,
wherein the compressed data output from the output terminal is multiplexed together with one or more types of compressed data.

6. The semiconductor device according to claim 3,
wherein the compressed data input to the input terminal is compressed data demultiplexed from multiplexed data which is multiplexed one or more types of compressed data, and
wherein the decompression section decompresses the demultiplexed and compressed data.

7. The semiconductor device according to claim 1,
wherein the compressed data is compressed according to a given compression standard.

8. The semiconductor device according to claim 2,
wherein the compressed data is compressed according to a given compression standard.

9. The semiconductor device according to claim 3,
wherein the compressed data is compressed according to a given compression standard.

10. The semiconductor device according to claim 4,
wherein the compressed data is compressed according to a given compression standard.

11. The semiconductor device according to claim 5,
wherein the compressed data is compressed according to a given compression standard.

12. The semiconductor device according to claim 6,
wherein the compressed data is compressed according to a given compression standard.

13. The semiconductor device according to claim 7,
wherein the given compression standard is an MPEG standard.

14. The semiconductor device according to claim 8,
wherein the given compression standard is an MPEG standard.

15. The semiconductor device according to claim 9,
wherein the given compression standard is an MPEG standard.

16. Electronic equipment comprising:
the semiconductor device according to claim 1; and
a demultiplexing section which demultiplexes compressed data corresponding to the semiconductor device from multiplexed data which is multiplexed one or more types of compressed data, and supplies the demultiplexed and compressed data to the semiconductor device.

17. Electronic equipment comprising:
the semiconductor device according to claim 2; and
a multiplexing section which generates multiplexed data by multiplexing one or more types of compressed data including compressed data supplied from the semiconductor device.

18. Electronic equipment comprising:
the semiconductor device according to claim 3;
a demultiplexing section which demultiplexes compressed data corresponding to the semiconductor device from multiplexed data which is multiplexed one or more types of compressed data, and supplies the demultiplexed and compressed data to the semiconductor device; and
a display section which is driven by the semiconductor device.

19. The electronic equipment according to claim 16, further comprising:
a circuit which transmits and receives the multiplexed data through a given communication network.

20. The electronic equipment according to claim 17, further comprising:
a circuit which transmits and receives the multiplexed data through a given communication network.

21. The electronic equipment according to claim 18, further comprising:
a circuit which transmits and receives the multiplexed data through a given communication network.
